(19) United States
(12) Patent Application Publication
(10) Pub. No.: US 2025/0300424 A1
(43) Pub. Date: Sep. 25, 2025

(54) CARRIER ARRANGEMENT, OPTOELECTRONIC COMPONENT WITH CARRIER ARRANGEMENT AND METHOD FOR PRODUCING AN OPTOELECTRONIC COMPONENT WITH CARRIER ARRANGEMENT

(71) Applicant: ams-OSRAM International GmbH, Regensburg (DE)

(72) Inventors: Florian Roider, Rettenbach (DE); Kurt-Juergen Lang, Regen (DE); Volker Zenger, Sinzing (DE)

(21) Appl. No.: 18/863,297

(22) PCT Filed: Apr. 18, 2023
(86) PCT No.: PCT/EP2023/060013

§ 371 Date: Nov. 5, 2024

(30) Foreign Application Priority Data
May 12, 2022 (DE) 102022111964.5

(51) Int. Cl. H01S 5/02315

(52) U.S. Cl. CPC H01S 5/02315

(57) ABSTRACT

In an embodiment a carrier arrangement includes a connection carrier and an insert body, wherein the connection carrier has at least one recess, wherein the insert body has a trench, which is arranged on a cover surface of the insert body, wherein the insert body is arranged in the recess of the connection carrier, wherein the trench does not completely penetrate the insert body in a vertical direction, and wherein the insert body does not extend completely through the connection carrier in the vertical direction.

### CROSS-REFERENCE TO RELATED APPLICATIONS

This patent application is a national phase filing under section 371 of PCT/EP2023/060013, filed Apr. 18, 2023, which claims the priority of German patent application no. 102022111964.5, filed May 12, 2022, each of which is incorporated herein by reference in its entirety.

### TECHNICAL FIELD

A carrier arrangement, an optoelectronic component with a carrier arrangement and a method for producing an optoelectronic component with a carrier arrangement are provided.

### SUMMARY

Embodiments provide a carrier arrangement to which optoelectronic devices can be applied particularly efficiently. Further embodiments provide an optoelectronic component, wherein the optoelectronic device comprises a particularly efficient connection to the carrier arrangement. Yet further embodiments provide methods, by which an optoelectronic device with a particularly efficient connection to the carrier arrangement can be produced.

According to at least one embodiment, the carrier arrangement comprises a connection carrier. The connection carrier may, for example, be a circuit board or a board or a printed circuit board, also PCB. The connection carrier is, for example, formed with an electrically insulating material and can include electrically conductive tracks. The electrically insulating material contains, for example, a plastic material, an epoxy resin-glass fiber composite such as FR4 or BT, an epoxy composite material (CEM materials, composite epoxy material) and/or a ceramic material.

According to at least one embodiment, the carrier arrangement comprises an insert body. The insert body can be three-dimensional. Furthermore, the insert body can comprise a main extension plane. In other words, the insert body can in particular comprise at least one side surface. The at least one side surface is preferably a surface of the insert body which runs perpendicular or almost perpendicular to a main extension plane of the insert body. The insert body can comprise at least one further side surface, which can be oriented almost parallel, at an angle or perpendicular to the at least one side surface. The further side surface may, for example, adjoin the at least one side surface or be arranged at a distance from the at least one side surface.

The insert body comprises, for example, a circular and/or rectangular base surface, that runs at least in places parallel to the main extension plane.

For example, the insert body is at least partially cylindrical and/or semi-cylindrical and/or cuboidal and/or pyramidal and/or conical.

In particular, the insert body comprises a surface on its top side. In particular, this is a cover surface of the insert body. The cover surface is oriented parallel or almost parallel to the main extension plane of the insert body, for example. The insert body comprises, for example, a bottom surface. The bottom surface is arranged on the side of the insert body facing away from the cover surface. The cover surface and/or the bottom surface can, for example, be oriented parallel to the base surface. For example, the base surface is the cover surface.

For example, the insert body comprises or consists of a metal. In particular, the insert body may be formed from copper or contain copper.

The insert body can be formed contiguously, in particular in one piece. For example, the insert body can be self-supporting. The insert body can be attached as an independent and/or prefabricated device. In particular, the insert body can be arranged as an independent and/or prefabricated device in the recess of the connection carrier. For example, the insert body is thus not first created in the recess.

The insert body can comprise an inner region and/or an edge region. The inner region and/or the edge region thereby preferably adjoins a cover surface of the insert body. In other words, the inner region of the insert body is, for example, an inner region of the cover surface of the insert body. The inner region of the insert body can be characterized in that the inner region of the insert body laterally adjoins the edge region of the insert body on at least one side. For example, the inner region of the insert body directly adjoins the edge region of the insert body laterally on at least one side. In particular, the inner region of the insert body is the region of the cover surface of the insert body to which an optoelectronic device can later be applied. The inner region is thus defined, for example, by the overlap of the insert body and the optoelectronic device.

The edge region is a further region of the cover surface of the insert body, which is later not covered by an optoelectronic device. In other words, the edge region is a further region of the cover surface of the insert body, which is different from the inner region of the insert body. The edge region can be formed contiguously. Alternatively, the edge region consists of at least two sections, for example, which are arranged on opposite sides of the insert body.

According to at least one embodiment, the connection carrier comprises at least one recess. The recess is preferably arranged at the top side of the connection carrier and/or is, for example, directly adjacent to the top side of the connection carrier. For example, the recess is alternatively or additionally adjacent to an underside of the connection carrier. For example, the recess comprises at least the extents of the insert body along the main extension plane. In particular, the recess is shaped in such a way that the insert body can be inserted into the recess. The recess can, for example, be larger than the insert body.

According to at least one embodiment, the insert body comprises a trench, which is arranged at a cover surface of the insert body.

The trench can comprise a main extension direction. The main extension direction is a direction along which the trench comprises the greatest extent and which runs parallel or almost parallel to the main extension plane of the insert body. The trench can comprise a depth. The depth of the trench is an extension of the trench in a direction perpendicular to a main extension plane of the insert body. The depth of the trench corresponds, for example, to a maximum of the height of the insert body, for example a maximum of 75% of the height of the insert body or, for example, a maximum of 50% of the height of the insert body. The height of the insert body corresponds to the extension of the insert body perpendicular to the main extension plane of the insert body in vertical direction. For example, the trench does not completely penetrate the insert body in vertical direction.

For example, the trench can extend in a straight line or almost straight line along the main extension direction. Alternatively, the trench can extend along the main extension direction, but thereby comprise several extension directions that run transverse, parallel and/or perpendicular to the main extension direction. In other words, the trench can be meander-shaped, for example.

For example, the trench can laterally, in directions perpendicular to the vertical direction, be completely surrounded by the insert body. Alternatively, the trench can, for example, at least partially adjoin the connection carrier. The trench preferably extends in the inner region and in the edge region of the insert body. For example, the trench can extend from the edge region through the inner region into the edge region.

The trench can comprise a shape in cross-section perpendicular to the extension direction, that corresponds approximately to a semicircle, a rectangle and/or a V-shape and/or a U-shape, for example. The trench is, for example, a cavity and/or a channel, in particular a degassing channel.

According to at least one embodiment, the insert body comprises at least one further trench. The insert body then comprises more than one trench, in particular a plurality of trenches. The at least one further trench can be formed at a distance from the trench. The at least one further trench can run at least partially transversely or perpendicularly or parallel to the trench. The at least one further trench can also be oriented completely transverse or perpendicular or parallel to the trench. Alternatively or additionally, the at least one further trench can merge into the trench, for example the trench and the at least one further trench comprise at least one intersection point. The at least one further trench can comprise the same properties as the trench. For example, the trenches have different properties, such as different depths and/or shapes and/or main extension directions. The trenches can comprise an area proportion of at most 80%, for example of at most 60%, in particular of at most 50% of the area formed by the cover surface of the insert body.

According to at least one embodiment, the insert body is arranged in the at least one recess of the connection carrier. The insert body can be flush with the connection carrier, at least on the side of the connection carrier at which the recess is arranged. For example, the insert body can be surrounded only laterally by the connection carrier. Alternatively, the cover surface of the insert body may not be flush or almost flush with a top side of the connection carrier. For example, the insert body can protrude from the connection carrier in order to ensure an efficient connection with a complementary formed and carrier arrangement-facing side of an optoelectronic device. The top side of the carrier arrangement can thus, for example, be adapted to a structure of a side of an optoelectronic device facing the carrier arrangement.

According to at least one embodiment, the carrier arrangement comprises a connection carrier and an insert body, wherein the connection carrier comprises at least one recess. The insert body comprises a trench, which is arranged at a cover surface of the insert body. Further, the insert body is arranged in the at least one recess of the connection carrier.

The carrier arrangement described here is based, among other things, on the idea that due to the trench in the insert body of the carrier arrangement gas generated during soldering, for example, can escape via the trench. Thus, little or no air bubbles, pores and/or gas inclusions are formed between the carrier and the optoelectronic device. Thereby, the thermal connection of the optoelectronic device to the carrier can be improved. Furthermore, the stability of the solder connection can be improved.

According to at least one embodiment, the trench extends transversely or perpendicularly to a side surface of the insert body. The trench can, for example, run parallel or almost parallel to a further side surface of the insert body.

According to at least one embodiment, the trench is directly adjacent to at least one side surface of the insert body. That the trench is directly adjacent to a side surface of the insert body can mean, for example, that the trench penetrates the insert body at its side surface and is adjacent to the connection carrier. For example, the trench is directly adjacent to the connection carrier. For example, the trench is only on one side laterally surrounded by the insert body. In this case, the connection carrier forms, for example, at least partially a side wall of the trench. For example, the trench is on at least one side not laterally surrounded by the insert body. That the trench is directly adjacent to at least one side surface of the insert body can mean, for example, that the trench is open on the at least one side surface. In other words, the trench partly comprises no boundary. For example, the trench can merge into a reservoir and/or can be configured to feed material into the reservoir or to remove material from the reservoir.

An idea of this embodiment is that the trench in the insert body can be created in a simplified manner. Furthermore, the trench can laterally comprise at least in places no boundary. Thereby, the trench can take up or discharge material more easily.

According to at least one embodiment, the trench is arranged partly in an inner region of the cover surface of the insert body and partly in an edge region of the insert body. The inner region and the edge region of the insert body can be regions of the cover surface of the insert body.

For example, the trench can be arranged in two regions of the edge region. In other words, the trench can extend from one region of the edge region of the cover surface on one side surface of the insert body to a further region of the edge region of the cover surface on a side surface opposite the one side surface. Thereby, the trench can extend through the inner region, for example.

An advantage of this embodiment is that the trench connects the region bounded between an optoelectronic device and the carrier arrangement with the surrounding medium. Thus, for example, air bubbles, pores and/or gas inclusions that arise and/or are trapped between the optoelectronic device and the carrier arrangement can escape via the trench. The mechanical and/or electrical and/or thermal connection between the optoelectronic device and the carrier arrangement can thereby be improved.

According to at least one embodiment, the trench merges into at least one further trench or intersects it, wherein the at least one further trench is at least partially aligned transversely and/or perpendicularly to the trench. For example, the trench and the at least one further trench comprise at least one intersection point.

Due to several trenches formed at a distance from each other, for example, the gas can be better removed from the air bubbles and/or pores.

According to at least one embodiment, the insert body comprises at least one further trench which runs parallel to the trench. The at least one further trench can, for example, be formed at a distance from the trench. The at least one further trench can comprise the same properties as the trench. Alternatively, the at least one further trench may differ from the trench, for example in the shape of the cross-section, the extent and/or the length.

An advantage of this embodiment is that by means of several trenches formed spaced apart from each other, the gas can be better removed from the gas inclusions.

Furthermore, a method for manufacturing a carrier arrangement is provided. The carrier arrangement is preferably producible by a method described herein. In other words, all features disclosed for the carrier arrangement are also disclosed for the method for manufacturing a carrier arrangement and vice versa.

According to at least one embodiment, the method for manufacturing a carrier arrangement comprises providing a connection carrier and/or an insert body.

According to at least one embodiment, the method for manufacturing a carrier arrangement comprises a method step in which a trench is created in an insert body. The trench is created, for example, by means of milling, punching, embossing, etching and/or by means of additive methods. For example, more than one trench can be created in the insert body. For example, the insert body comprises at least two trenches.

According to at least one embodiment, the method for manufacturing a carrier arrangement comprises a step in which a recess is created in the connection carrier. The recess is created, for example, by milling and/or punching. For example, the recess can extend across the entire width of the connection carrier. Alternatively, the recess can comprise the dimensions of the insert body along the main extension plane, in each case with a tolerance of, for example, a maximum of 50%, for example a maximum of 20% or for example a maximum of 10%.

According to at least one embodiment, the method for manufacturing a carrier arrangement comprises arranging the insert body in the recess of the connection carrier. Thereby, the insert body can already comprise a trench prior to the arrangement of the insert body in the recess of the connection carrier. Alternatively or additionally, the trench can be created in the insert body after the arrangement of the insert body in the recess of the connection carrier. The arrangement of the insert body in the recess of the connection carrier comprises, in particular, the insertion of the insert body into the recess. Subsequently, the insert body is mechanically connected to the connection carrier. The connection carrier can, for example, comprise a hardenable material, for example a resin. For example, the insert body is mechanically connected to the connection carrier using the material of the connection carrier, for example using resin that is not completely hardened. The resin that is not completely hardened forms an adhesive, for example. For example, arranging the insert body in the recess of the connection carrier comprises temperature pressing. In this case, the insert body is placed in the recess of the connection carrier and reshaped by the connection carrier using temperature pressing. Thereby, the material of the connection carrier is deformable due to the temperature pressing, for example. By means of temperature pressing, the insert body is mechanically connected to the connection carrier, for example.

An optoelectronic component is provided. The carrier arrangement is preferably arranged in an optoelectronic component described herein. In other words, all features disclosed for the carrier arrangement are also disclosed for the optoelectronic component and vice versa.

According to at least one embodiment, the optoelectronic component comprises at least one optoelectronic device. The optoelectronic device can, for example, be designed as an optoelectronic device configured for radiation generation and/or for radiation detection. For example, the optoelectronic device is an optoelectronic device that requires a good thermal connection to dissipate heat. The optoelectronic device is, for example, a light-emitting diode, a light-emitting diode chip, a laser diode, a laser diode chip, a photodiode or a photodiode chip.

According to at least one embodiment, the at least one optoelectronic device is applied to the carrier arrangement and covers the insert body at least in places. For example, the optoelectronic device covers the insert body completely or almost completely. Alternatively, the insert body can comprise a greater extension in at least one direction than the optoelectronic device along the same direction. In other words, in at least one direction, the optoelectronic device may not completely cover the insert body.

According to at least one embodiment, the optoelectronic component comprises a carrier arrangement described herein and at least one optoelectronic device, wherein the at least one optoelectronic device is applied to the carrier arrangement and covers the insert body at least in places.

An idea of this embodiment is to provide an optoelectronic component in which there is a particularly efficient thermal connection between the optoelectronic device and the carrier arrangement. Furthermore, the distribution of a connecting material introduced between the carrier arrangement and the optoelectronic device can be improved by the trench. The variance of the distribution of the connecting material can thus be reduced. Furthermore, due to the presence of at least one trench a distortion of the optoelectronic component due to different expansion coefficients of the insert body and the optoelectronic device can at least partially be reduced.

According to at least one embodiment, the at least one optoelectronic device only partially covers the trench of the insert body of the carrier arrangement. The trench extends, for example, from an inner region of the insert body, which is covered by the optoelectronic device, to an edge region of the insert body, which is not covered by the optoelectronic device. For example, the insert body comprises at least one trench. If the insert body comprises more than one trench, the at least one further trench can also extend from an inner region of the insert body to an edge region of the insert body. In other words, the optoelectronic device is applied to the insert body, for example, in such a way that the optoelectronic device does not completely cover the trench, several trenches or all trenches of the insert body. For example, the optoelectronic device only partially covers the trench, several trenches or all trenches.

Due to the trench being only partially covered by the optoelectronic device, the air bubbles, pores and/or gas inclusions can be effectively guided away from the optoelectronic device via the trench.

According to at least one embodiment of the optoelectronic component, a connecting material is at least partially arranged between the carrier arrangement and the optoelectronic device. The connecting material is, for example, a material that is configured to connect the optoelectronic device electrically and/or mechanically to the connection carrier. For example, the connecting material contains an adhesive, a sintered material and/or a solder. In particular, the solder can be based on tin.

An advantage of this embodiment of the optoelectronic component is that an efficient connection of the optoelectronic device to the carrier arrangement by the connecting material takes place. In particular, a better thermal connection of the optoelectronic device to the carrier arrangement takes place.

According to at least one embodiment of the optoelectronic component, the trench of the insert body is at least partially filled with a connecting material. This can mean that the trench of the insert body is only partially filled with the connecting material. For example, the trench is partially or completely covered with the connecting material. That the trench is covered can thereby mean that only the opening of the trench is covered. Alternatively or additionally, one or more side surfaces of the trench facing the trench may be wetted with the connecting material. Preferably, the trench of the insert body is completely filled with the connecting material.

An advantage of this embodiment is that the contact surface of the connection of the optoelectronic device to the carrier arrangement is increased by the trench being at least partially filled with the connecting material. Thus, the thermal connection of the optoelectronic device to the insert body can be improved. In particular, the heat dissipation from the optoelectronic device via the insert body is improved.

According to at least one embodiment of the optoelectronic component, the connecting material comprises a soldering material and/or consists thereof. For example, the soldering material is a soft solder. In particular, the soldering material comprises tin, silver and/or copper.

The use of soldering material, for example, can enable a good connection between the carrier arrangement and the optoelectronic device.

According to at least one embodiment of the optoelectronic component, the optoelectronic device comprises, on a side facing the insert body, a protrusion which is configured to engage in the trench of the insert body, wherein the optoelectronic device is adjusted by means of the protrusion and/or is electrically and/or mechanically connected to the insert body. The protrusion can, for example, be smaller than the trench in order to allow the protrusion to engage in the trench. For example, the protrusion may not be in direct contact with the trench when engaging in the trench. Alternatively, the protrusion can be partially in direct contact with the trench and/or partially or completely fill the trench in at least one direction. For example, the protrusion engages in the trench in an inner region of the insert body.

Due to the protrusion the contact surface of the connection between the optoelectronic device and the carrier arrangement can be increased. Thus, the thermal connection of the optoelectronic device to the insert body can be improved. In this way, the heat dissipation from the optoelectronic device via the insert body is improved. In addition, an optoelectronic component with improved stability can be created by the protrusion engaging in the trench.

Furthermore, a method for producing an optoelectronic component is provided. The optoelectronic component is preferably producible by a method described herein. In other words, all features disclosed for the optoelectronic component are also disclosed for the method for producing an optoelectronic component and vice versa.

According to at least one embodiment of the method for producing an optoelectronic component, the method comprises a method step in which a carrier arrangement is provided.

The carrier arrangement is in particular a previously described carrier arrangement.

According to at least one embodiment, the method comprises a method step wherein at least one optoelectronic device is applied to the carrier arrangement.

According to at least one embodiment, the method comprises a step wherein the optoelectronic device is electrically and/or mechanically and/or thermally connected to the carrier arrangement.

According to at least one embodiment of the method for producing an optoelectronic component, a carrier arrangement is provided. Subsequently, an optoelectronic device is applied to the carrier arrangement. The optoelectronic device is electrically and/or mechanically and/or thermally connected to the carrier arrangement.

With this embodiment of the method, for example, an optoelectronic component can be produced in which there is a particularly efficient thermal connection between the optoelectronic device and the carrier arrangement. Furthermore, the distribution of a connecting material introduced between the carrier arrangement and the optoelectronic device can be improved by the trench. Furthermore, the presence of at least one trench can at least partially reduce a distortion of the optoelectronic component due to different expansion coefficients of the insert body and the optoelectronic device.

According to at least one embodiment of the method for producing an optoelectronic component, the optoelectronic device comprises a protrusion on a side facing the insert body, which engages in the trench of the insert body when the optoelectronic device is applied to the insert body. The protrusion can, for example, be smaller than the trench.

An advantage of this embodiment is that the contact surface of the connection between the optoelectronic device and the carrier arrangement is increased due to the protrusion. Thus, the thermal connection of the optoelectronic device to the insert body can be improved. Thus, the heat dissipation from the optoelectronic device via the insert body is improved. In addition, due to the protrusion engaging in the trench, an optoelectronic component with improved stability can be created.

According to at least one embodiment of the method for producing an optoelectronic component, the optoelectronic device does not completely cover a trench of the insert body. For example, the trench of the insert body protrudes beyond the optoelectronic device in at least one direction.

Because of the trench being only partially covered by the optoelectronic device, the air bubbles, pores and/or gas inclusions can be effectively guided away from the optoelectronic device via the trench.

According to at least one embodiment of the method for producing an optoelectronic component, a connecting material is applied to at least a part of the insert body prior to the application of the at least one optoelectronic device.

Due to the connecting material, for example, an efficient connection of the optoelectronic device to the carrier arrangement can take place.

According to at least one embodiment of the method for producing an optoelectronic component, the trench is configured to, after the application of the at least one optoelectronic device, guide a connecting material from an edge region of the cover surface of the insert body to an inner region of the cover surface of the insert body.

For example, the connecting material is applied to the trench. The connecting material can be guided through the trench by means of capillary forces. The extent of the trench can thereby be adapted to the connecting material to enable a guidance of the connecting material in the trench. The connecting material infiltrates, for example, the space between the carrier arrangement and the optoelectronic device. For example, the connecting material is applied to the trench in the edge region. Alternatively or additionally, the connecting material can be taken from a reservoir by means of the trench adjacent to a side surface of the insert body and introduced into the space between carrier arrangement and optoelectronic device by means of the trench.

An idea of this embodiment is that the connecting material can only be arranged between the carrier arrangement and the optoelectronic device after the application of the optoelectronic device. Since the connecting material can be taken from a reservoir by the trench, the connecting material does not have to be arranged directly between the carrier arrangement and the optoelectronic device. An excess of connecting material between the carrier arrangement and the connecting material can thus be avoided.

### BRIEF DESCRIPTION OF THE DRAWINGS

In the following, the carrier arrangement described herein, the optoelectronic component with carrier arrangement described herein as well as the methods for producing an optoelectronic component with carrier arrangement described herein are explained in more detail in connection with exemplary embodiments and the associated figures.

FIGS. 1A and 1B show a schematic top view and a schematic cross-section of a connection carrier with insert body, respectively;

FIGS. 2A, 2B, 2C and 2D show different views of an optoelectronic device according to an exemplary embodiment and of a carrier arrangement according to an exemplary embodiment, respectively;

FIGS. 3A, 3B and 3C show different views of an optoelectronic device according to a further exemplary embodiment and a carrier arrangement according to a further exemplary embodiment, respectively;

FIGS. 4A, 4B and 4C show different views of an optoelectronic device according to a further exemplary embodiment and of a carrier arrangement according to a further exemplary embodiment, respectively;

FIGS. 5A, 5B, 5C and 5D show an exemplary embodiment of a method for producing an optoelectronic device; and

FIG. 6 shows a further exemplary embodiment of a method for producing an optoelectronic device.

Elements that are identical, similar or have the same effect are marked with the same reference signs in the figures. The figures and the proportions of the elements shown in the figures are not to be regarded as being true to scale. Rather, individual elements may be shown exaggeratedly large for better visualization and/or better comprehensibility.

### DETAILED DESCRIPTION OF ILLUSTRATIVE EMBODIMENTS

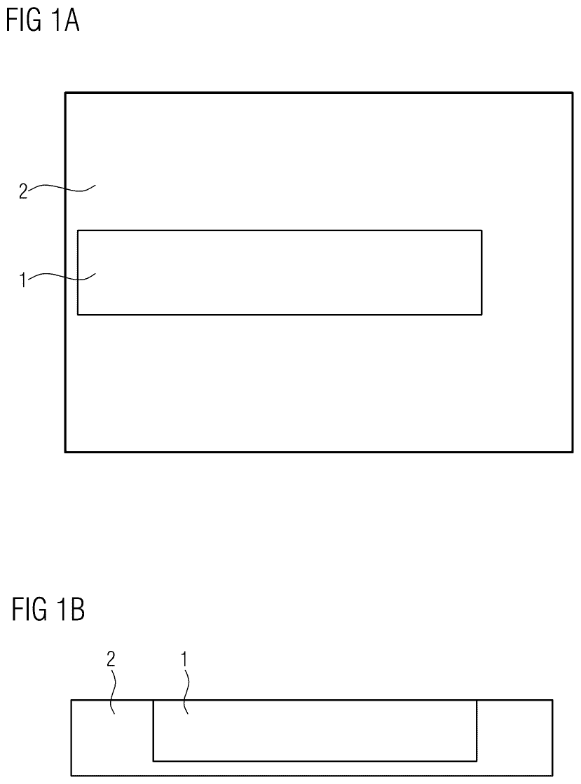

FIG. 1A shows a top view of a carrier arrangement 5. The carrier arrangement 5 comprises a connection carrier 2 and an insert body 1.

FIG. 1B shows a cross-section of a carrier arrangement 5. The insert body 1 is inserted into a recess of the connection carrier 2.

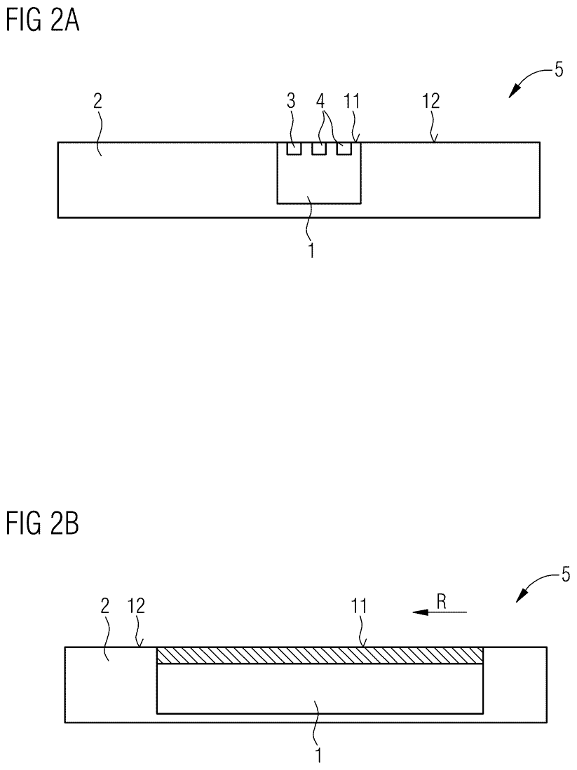

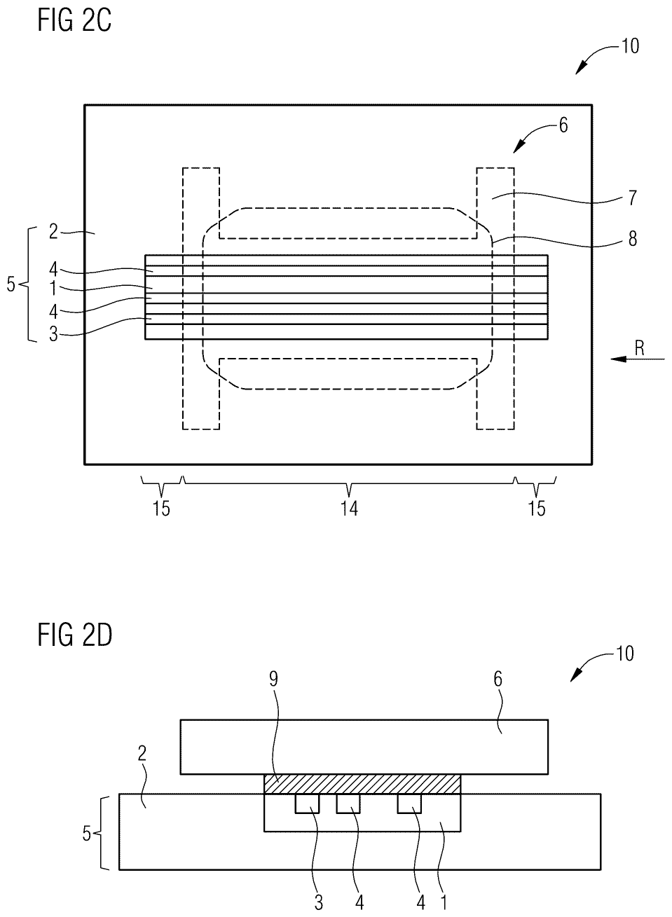

In the views of FIGS. 2A to 2D, a carrier arrangement 5 and an optoelectronic component 10 according to an exemplary embodiment are shown.

FIG. 2A shows a schematic cross-section of a carrier arrangement 5 according to an exemplary embodiment. A cover surface 11 of the insert body 1 is on a top side of the carrier arrangement 5 flush or almost flush with a top side 12 of the connection carrier 2. Alternatively or additionally, not shown, a bottom surface of the insert body can be flush or almost flush with an underside of the connection carrier. The insert body 1 is arranged in a recess of the connection carrier 2. The insert body 1 comprises a trench 3 and two further trenches 4. The trenches 3, 4 are spaced apart from each other. The trenches 3, 4 are arranged at the cover surface 11 of the insert body 1.

FIG. 2B shows a schematic cross-section perpendicular to the cross-section shown in FIG. 2A through a carrier arrangement 5 according to an exemplary embodiment. The hatched area of the insert body 1 represents an area of the insert body 1 which comprises a lower density than the rest of the insert body 1 due to the trenches 3, 4. In the exemplary embodiment shown here, the trench 3 extends along a main extension direction R parallel to the main extension plane of the insert body 1 over the entire extension of the insert body 1 along the main extension direction R.

FIG. 2C shows a top view of an optoelectronic component 10 with a carrier arrangement 5 according to an exemplary embodiment.

The carrier arrangement 5 comprises a connection carrier 2 and an insert body 1. The insert body 1 is arranged in a recess of the connection carrier 2.

The insert body 1 comprises a trench 3, which is arranged at a cover surface 11 of the insert body. The trench extends, for example, transversely or perpendicularly to a side surface of the insert body. The insert body 1 can comprise more than one trench 3. For example, the insert body can comprise at least one further trench 4. The insert body 1 shown here comprises two further trenches 4. The further trenches 4 are spaced apart from one another and are each formed at a distance from the trench 3. The further trenches 4 run parallel to the trench 3. The trenches 3, 4 extend perpendicular to a side surface of the insert body 1 along the insert body 1 to a further side surface of the insert body 1. Thereby, the trenches 3, 4 can be directly adjacent to at least one side surface of the insert body 1. The further side surface of the insert body 1 is arranged at a side of the insert body 1 opposite the side surface.

The optoelectronic component 10 comprises an optoelectronic device 6 (shown dashed). The optoelectronic device 6 comprises a solder pad 7 as well as a chip 8. The optoelectronic device 6 covers the insert body 1 at least in places. The regions in which the optoelectronic device 6 covers the insert body 1 are an inner region 14 of the cover surface 11 of the insert body. Regions of the insert body 1 not covered by the optoelectronic device 6 form an edge region 15 of the cover surface 11 of the insert body. The trench 3 can be arranged partly in an inner region 14 of the insert body 1 and partly in an edge region 15 of the insert body 1.

For example, the optoelectronic device 6 is applied to the insert body 1 in such a way that the optoelectronic component does not completely cover the trench 3 and the at least one further trench 4 of the insert body 1. For example, the optoelectronic device 6 only partially covers the trench 3.

FIG. 2D shows a schematic cross-section through the optoelectronic component 10. On a top side of the carrier arrangement 5 an optoelectronic device 6 is applied. The top side of the carrier arrangement 5 is in particular the side that is at least partially formed by the cover surface 11 of the insert body 1, at which the trench 3 is arranged.

A connecting material 9 is arranged at least in places between the optoelectronic device 6 and the carrier arrangement. For example, the connecting material 9 comprises a soldering material and/or consists thereof. The connecting material 9 is, for example, a solder, in particular a solder paste.

The optoelectronic device 6 can, not shown, comprise a protrusion on a side facing the insert body 1, which is configured to engage in the trench 3 of the insert body. The optoelectronic device 6 is then adjusted and/or electrically and/or mechanically connected to the insert body 1 by means of the protrusion, for example.

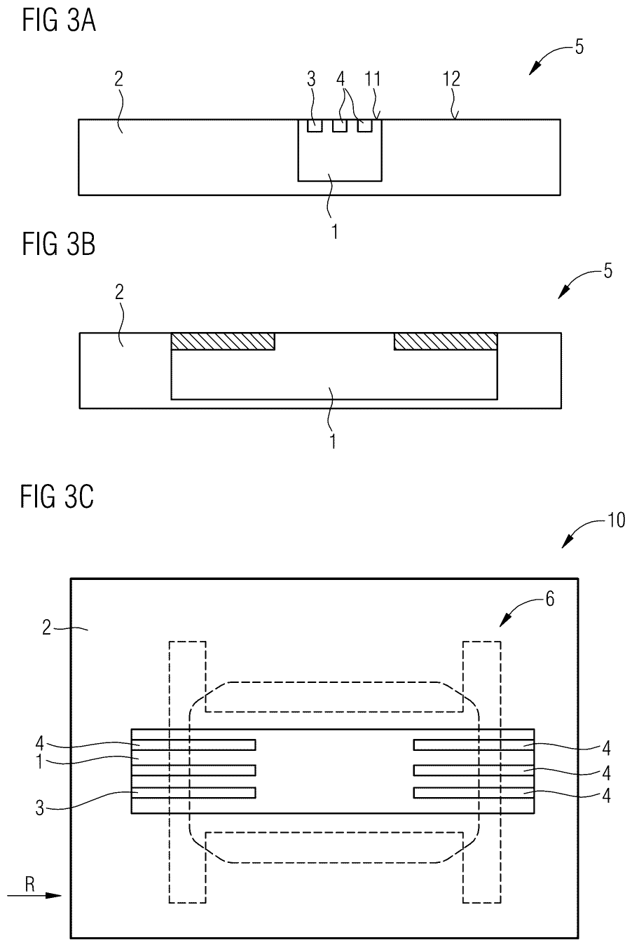

In the views of FIGS. 3A to 3C, a carrier arrangement 5 and an optoelectronic component 10 are shown according to a further exemplary embodiment.

FIG. 3A shows a schematic cross-section through a carrier arrangement 5 according to a further exemplary embodiment. The carrier arrangement 5 of FIG. 3A differs from the carrier arrangement 5 of FIG. 2A in that the trench 3 does not extend completely along a main extension direction R of the trench 3 over an extent of the insert body 1 along the main extension direction R. In other words, the trench 3 extends from a side surface in a direction away from the side surface only partially along the insert body 1. In particular, the trench 3 extends perpendicular to the side surface.

The insert body comprises at least one further trench 4. The at least one further trench 4 is formed at a distance from the trench 3. The at least one further trench 4 can otherwise comprise the same properties as the trench 3.

FIG. 3B shows a schematic cross-section perpendicular to the cross-section shown in FIG. 3A through a carrier arrangement 5 according to a further exemplary embodiment. Analogous to the difference described above, the exemplary embodiment shown in FIG. 3B differs from the exemplary embodiment shown in FIG. 2B in that the trench 3 extends along a main extension direction R only partially over the extent of the insert body 1 along the main extension direction R. The hatched regions show regions of the insert body in which the trench 3 is arranged.

FIG. 3C shows a top view of an optoelectronic component 10 with a carrier arrangement 5 shown in FIGS. 3A and 3B.

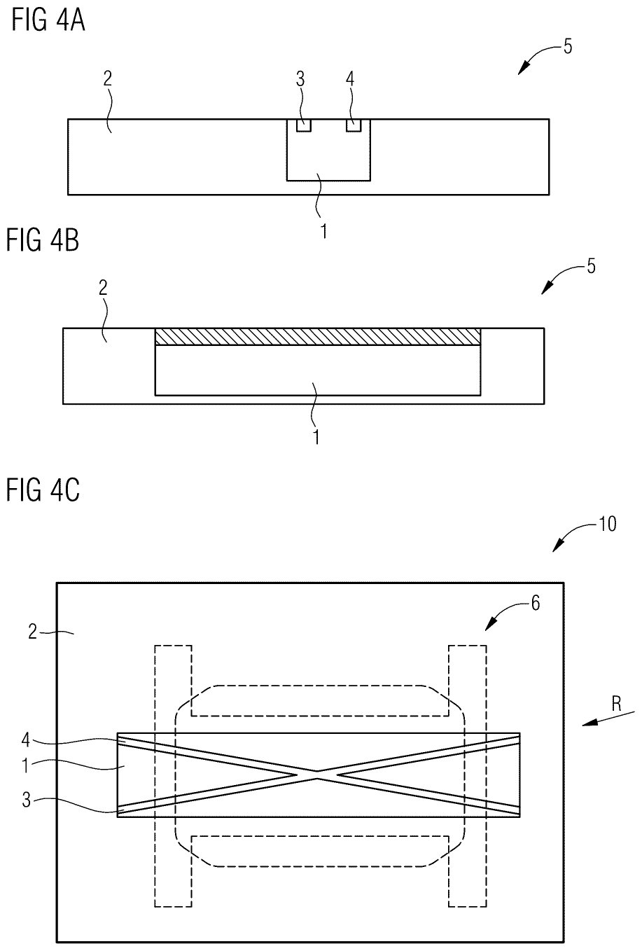

In FIGS. 4A to 4C schematic cross-sections of a carrier arrangement 5 and a top view of an optoelectronic component 10 according to a further exemplary embodiment are shown.

The carrier arrangement 5 according to the exemplary embodiment shown in FIGS. 4A, 4B and 4C comprises a trench 3 and a further trench 4. For example, the trench 3 merges into at least one further trench 4 or intersects it. The further trench 4 is thereby at least partially aligned transversely or perpendicularly to the trench 3. The trenches 3, 4 run at an angle to one another and merge into one another. In other words, the trenches 3, 4 intersect.

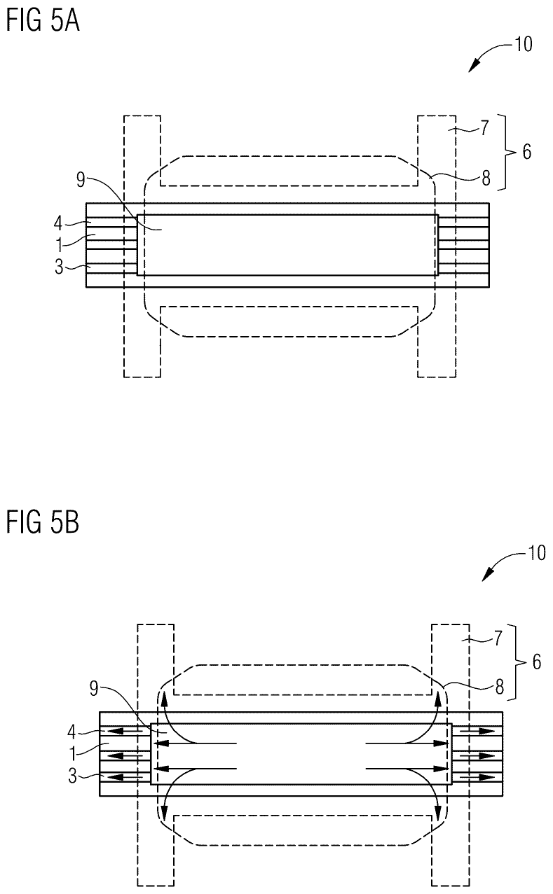

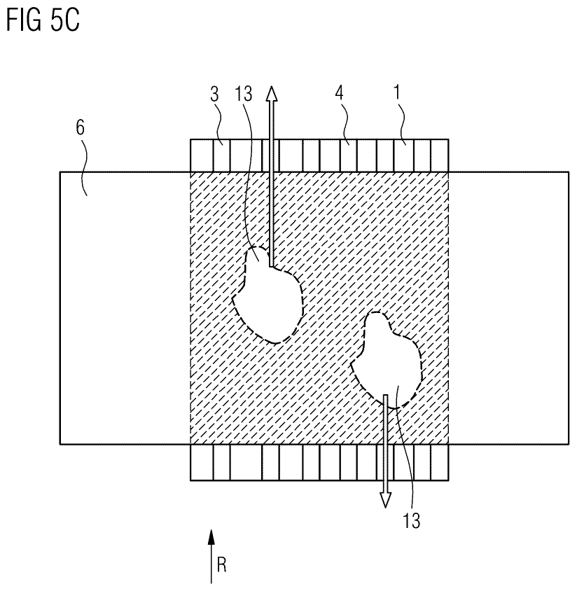

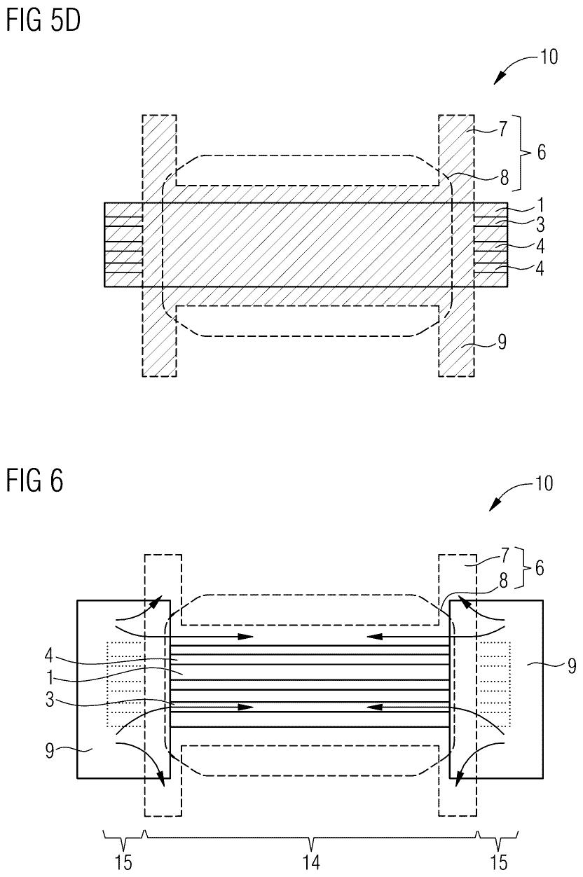

FIGS. 5A, 5B, 5C and 5D show an exemplary embodiment of a method for producing an optoelectronic component.

In a first method step, FIG. 5A, a carrier arrangement 5 according to an exemplary embodiment and an optoelectronic device 6 are provided. A connecting material 9, for example a solder paste, is applied to the insert body 1 in the carrier arrangement 5. An optoelectronic device 6 is arranged on the connecting material 9. The optoelectronic device 6 can comprise a protrusion, not shown, which engages in the trench 3 of the insert body when the optoelectronic device 6 is applied to the insert body 1. The optoelectronic device 6 covers, after the application, the trench 3 of the insert body 1 only in places.

FIGS. 5B and 5C show a method step following the step shown in FIG. 5A. The connecting material 9 spreads, for example, between the carrier arrangement 5 and the optoelectronic device 6. In particular, if the connecting material 9 comprises a solder paste, the optoelectronic component 10 is heated subsequent to the method step described in FIG. 5A. Thereby, for example, a metal contained in the solder paste liquefies and/or a solvent contained in the solder paste vaporises. The vaporized solvent forms, for example, gas-filled pores 13 between the carrier arrangement 5 and the optoelectronic device 6. The pores 13 are, for example, gas inclusions. The connecting material 9 can penetrate into the trench 3. For example, the portion of the connecting material 9 that is vaporized during heating and is therefore subsequently gaseous is led away through the trench 3 from a position between the carrier arrangement 5 and the optoelectronic device 6 to a region of the carrier arrangement 5 that is not covered by the optoelectronic device 6.

FIG. 5D shows a preferred arrangement of the connecting material in a finished optoelectronic component 10 according to an exemplary embodiment, in which the optoelectronic device 6 is electrically and/or mechanically and/or thermally connected to the carrier arrangement 5. The connecting material 9 (shown hatched here) spreads, for example, between the carrier arrangement 5 and the optoelectronic device 6. Preferably, the connecting material 9 wets a solder pad 7 of the optoelectronic device 6 completely or almost completely. Preferably, no gas-filled pores are arranged between the carrier arrangement 5 and the optoelectronic device 6. For example, the trench 3 of the insert body 1 is at least partially filled with the connecting material 9.

In FIG. 6 a further method for producing an optoelectronic component 10 according to an exemplary embodiment is shown. Thereby, first, the carrier arrangement 5 with the insert body 1 comprising the trench 3 is provided. An optoelectronic device 6 is applied to the top side of the carrier arrangement 5. The top side of the carrier arrangement 5 is the side of the carrier arrangement 5 that is at least partially formed by the cover surface 11 of the insert body.

Subsequently, for example, a connecting material 9 is partially applied to the part of the insert body 1 and/or the connection carrier 2 not covered by the optoelectronic device 6. For example, the connecting material 9 is arranged on and/or in the trench 3. The trench 3 is, for example, configured to guide the connecting material 9 between the carrier arrangement 5 and the optoelectronic device 6. The connecting material 9 spreads in the trench 3 by means of capillary forces, for example. The trench 3 is configured to guide a connecting material from an edge region 15 to an inner region 14 of the cover surface 11 of the insert body 1. The spreading of the connecting material 9 is indicated here by arrows.

Unlike shown, the connecting material 9 can also infiltrate the space between carrier arrangement 5 and optoelectronic device 6 only from one side of the optoelectronic device 6.

Preferably, the trench 3 in the finished optoelectronic component 10 is completely filled with the connecting material 9. In this way, for example, an efficient connection between the carrier arrangement 5 and the optoelectronic device 6 can be achieved.

The invention is not limited to the description based on the exemplary embodiments. Rather, the invention comprises any new feature as well as any combination of features, which includes in particular any combination of features in the patent claims, even if this feature or this combination itself is not explicitly stated in the patent claims or exemplary embodiments.

1.-18. (canceled)

19. A carrier arrangement comprising:
a connection carrier; and
an insert body,
wherein the connection carrier comprises at least one recess,
wherein the insert body comprises a trench, which is arranged on a cover surface of the insert body,
wherein the insert body is arranged in the recess of the connection carrier,
wherein the trench does not completely penetrate the insert body in a vertical direction, and
wherein the insert body does not extend completely through the connection carrier in the vertical direction.

20. The carrier arrangement according to claim 19, wherein the trench extends transversely or perpendicularly to a side surface of the insert body.

21. The carrier arrangement according to claim 19, wherein the trench is directly adjacent to at least one side surface of the insert body.

22. The carrier arrangement according to claim 19, wherein the trench is arranged partly in an inner region of the insert body and partly in an edge region of the insert body.

23. The carrier arrangement according to claim 19, wherein the trench merges into or intersects at least one further trench, and wherein the further trench is at least partially oriented transversely or perpendicularly to the trench.

24. The carrier arrangement according to claim 19, further comprising at least one further trench running parallel to the trench.

25. The carrier arrangement according to claim 19, wherein the insert body comprises a metal.

26. An optoelectronic component comprising:
the carrier arrangement according to claim 19; and
at least one optoelectronic device arranged at the carrier arrangement and covering the insert body at least in places.

27. The optoelectronic component according to claim 26, wherein the at least one optoelectronic device only partially covers the trench of the insert body.

28. The optoelectronic component according to claim 26, further comprising, at least in places, a connecting material arranged between the carrier arrangement and the optoelectronic device.

29. The optoelectronic component according to claim 28, wherein the trench of the insert body is at least partially filled with the connecting material.

30. The optoelectronic component according to claim 28, wherein the connecting material comprises a soldering material and/or consists thereof.

31. The optoelectronic component according to claim 26, wherein the optoelectronic device comprises, on a side facing the insert body, a protrusion, which is configured to engage in the trench of the insert body, wherein the optoelectronic device by the protrusion is adjusted and/or electrically and/or mechanically connected to the insert body.

32. A method for producing the optoelectronic component according to claim 26, the method comprising:
providing the carrier arrangement;
applying the at least one optoelectronic device to the carrier arrangement; and
electrical and/or mechanical and/or thermal connecting of the optoelectronic device to the carrier arrangement.

33. The method according to claim 32, wherein the optoelectronic device comprises a protrusion on a side facing the insert body, which engages in the trench of the insert body when the optoelectronic device is applied to the insert body.

34. The method according to claim 32, wherein the optoelectronic device covers the trench of the insert body only in places.

35. The method according to claim 32, further comprising applying a connecting material to at least a part of the insert body prior to applying the at least one optoelectronic device.

36. The method according to claim 32, wherein the trench is configured to conduct a connecting material from an edge region of the cover surface of the insert body to an inner region of the cover surface of the insert body after applying the at least one optoelectronic device.

37. An optoelectronic component comprising:
a carrier arrangement; and
at least one optoelectronic device,
wherein the carrier arrangement comprises a connection carrier and an insert body,
wherein the connection carrier comprises at least one recess,
wherein the insert body comprises a trench, which is arranged on a cover surface of the insert body,
wherein the insert body is arranged in the recess of the connection carrier,
wherein the trench does not completely penetrate the insert body in vertical direction,
wherein the at least one optoelectronic device is arranged at the carrier arrangement covering the insert body at least in places, and
wherein the at least one optoelectronic device only partially covers the trench of the insert body.
